(19) United States
(12) Patent Application Publication
(10) Pub. No.: US 2006/0151810 A1
(43) Pub. Date: Jul. 13, 2006

(54) Semiconductor device and computer program product for designing the same

(75) Inventor: Shinichiro Ohshige, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/321,448

(22) Filed: Dec. 30, 2005

(30) Foreign Application Priority Data
Jan. 12, 2005 (JP) 2005-005749

(51) Int. Cl. H01L 27/10

(52) U.S. Cl. 257/207

(57) ABSTRACT

A semiconductor device has: a plurality of first power supply wires formed in a first wiring layer; a plurality of second power supply wires formed in a second wiring layer; and a plurality of vias connecting between the first wiring layer and the second wiring layer. The plurality of second power supply wires overlap the plurality of first power supply wires at a plurality of intersections. The plurality of vias are arranged regularly at a part of the plurality of intersections.

### BACKGROUND OF THE INVENTION

1. Field of the Invention

The present invention relates to a semiconductor device and a technology for designing the semiconductor device. In particular, the present invention relates to a layout of power supply wires in a semiconductor device.

2. Description of the Related Art

In designing an LSI, it is essential to utilize a computer in order to reduce time for the designing and verifying and eliminate human errors. Such a system utilizing a computer for designing a semiconductor device is called a CAD (Computer Aided Design) system. According to a cell-based LSI design method, a plurality of cells are developed as a library. A designer designs an LSI by using the CAD and arranging desired cells in a layout space defined on the computer. As a result, a layout data representing a configuration of the designed LSI can be generated.

In a conventional LSI designing, power supply wires (power supply lines, ground lines) are arranged in the following manner. FIG. 1 schematically shows the arrangement of power supply wires in a conventional semiconductor device. As shown in FIG. 1, power supply lines 111 and ground lines 112 are formed in parallel along an X-direction, for example, in a wiring layer M1 of multi-wiring layers. The power supply lines 111 and the ground lines 112 are formed alternately. In addition, power supply lines 121 and ground lines 122 are formed in parallel along a Y-direction, for example, in a wiring layer M4 of the multi-wiring layers. The power supply lines 121 and the ground lines 122 are formed alternately.

The plurality of power supply lines 121 overlap the plurality of power supply lines 111 at a plurality of intersections, and vias 131 connecting between the power supply lines 111 and the power supply lines 121 are formed at all of the plurality of intersections. Also, the plurality of ground lines 122 overlap the plurality of ground lines 112 at a plurality of intersections, and vias 132 connecting between the ground lines 112 and the ground lines 122 are formed at all of the plurality of intersections. Here, each of the vias 131 and the vias 132 has a stacked via structure.

A relevant technology is disclosed in Japanese Laid Open Patent Application (JP-P2003-124334A). A semiconductor integrated circuit device disclosed in the patent document has first power supply wires formed in a first wiring layer located above a circuit block and second power supply wires formed in a second wiring layer located above the first wiring layer. The wiring density of the first power supply wires is dependent on the kind of the circuit block located below. The second power supply wires are formed uniformly. Vias are formed at intersections between the first power supply wires and the second power supply wires, respectively.

### SUMMARY OF THE INVENTION

The present invention has recognized the following points. In FIG. 1, each of the vias 131 and the vias 132 has a stacked via structure. Therefore, it is necessary to form other wirings to circumvent the vias 131 and 132, for example, in a wiring layer M2 between the above-mentioned wiring layers M1 and M4. This deteriorates wiring performance.

In an aspect of the present invention, a semiconductor device has: a plurality of first power supply wires formed in a first wiring layer; a plurality of second power supply wires formed in a second wiring layer; and a plurality of vias connecting between the first wiring layer and the second wiring layer. The plurality of second power supply wires overlap the plurality of first power supply wires at a plurality of intersections. The plurality of vias are arranged regularly at a part of the plurality of intersections. Here, the regular arrangement pattern means a pattern constituted by repetition of a predetermined pattern.

According to the present invention, as described above, the plurality of vias are arranged only at the above-mentioned partial intersections. It is therefore possible to route wires freely in a region where the vias are not placed. Therefore, the wiring performance is improved. Moreover, since the plurality of vias are arranged only at the partial intersections, it is possible to reduce the amount of layout data that is produced at the time of the computer-aided designing. Therefore, computing load in processing the layout data is reduced.

Furthermore, according to the present invention, the plurality of vias are arranged regularly (systematically) in accordance with a predetermined rule. As a result, data (language) describing the vias in the above-mentioned layout data also have certain regularity. Thus, data compression rate with respect to the layout data is improved. Therefore, computing load in processing the layout data is reduced.

The above-mentioned structure of the power supply wires can be applied to an ASIC (Application Specific Integrated Circuit). In this case, the structure of the power supply wires according to the present invention is provided in a base layer beforehand. In a customize layer above the base layer, circuits are designed in accordance with a user's request. In the customize layer, the vias are formed at positions corresponding to those in the base layer on the basis of the same rule as in the base layer. According to the present invention, since the arrangement of the vias in the base layer has a certain regularity, the user can easily arrange vias in the customize layer. As a result, the design of the ASIC becomes easier.

According to the semiconductor device and a computer program product for designing the same of the present invention, the wiring performance can be improved.

According to the semiconductor device and a computer program product for designing the same of the present invention, the computing load in processing the layout data representing the layout of the semiconductor device can be reduced.

According to the semiconductor device and a computer program product for designing the same of the present invention, the designing of an ASIC and an IP (Intellectual Property) core becomes easier.

### BRIEF DESCRIPTION OF THE DRAWINGS

The above and other objects, advantages and features of the present invention will be more apparent from the following description taken in conjunction with the accompanying drawings, in which:

FIG. 1 is a plan view showing a structure of a conventional semiconductor device;

FIG. 2 is a plan view showing an example of a structure of a semiconductor device according to an embodiment of the present invention;

FIG. 3 is a plan view showing another example of the structure of the semiconductor device according to the embodiment of the present invention;

FIG. 4 is a block diagram showing a configuration of a semiconductor device design program according to the embodiment of the present invention;

FIG. 5 is a flowchart showing a method of designing the semiconductor device according to the embodiment of the present invention;

FIG. 6 is a conceptual view showing multiple layout layers; and

FIG. 7 is a sectional view showing a structure of an ASIC.

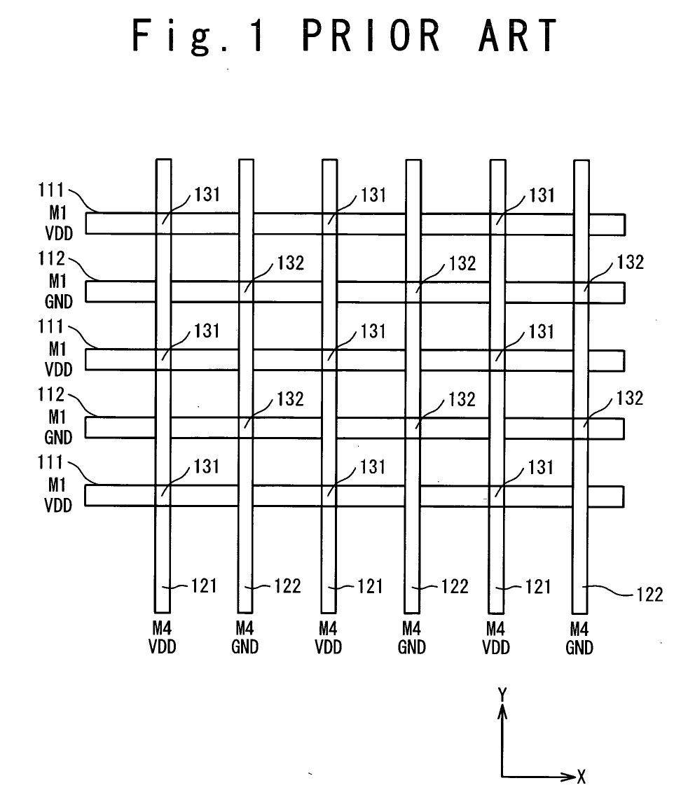

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed. A semiconductor device, a semiconductor device design system and a semiconductor device design program will be described below with reference to the accompanying drawings.

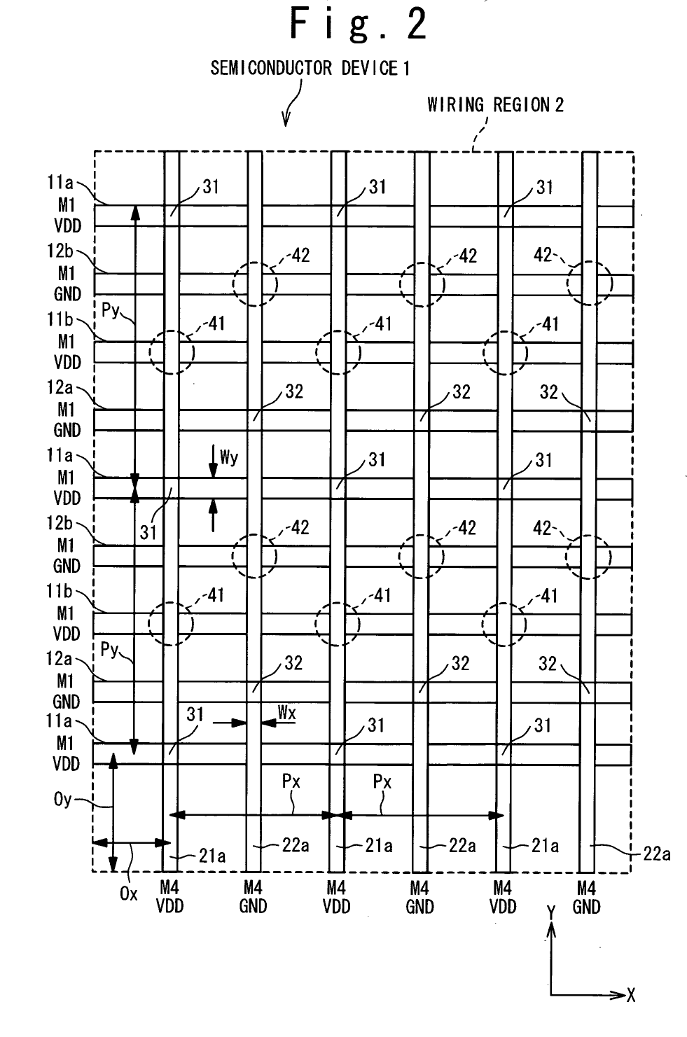

FIG. 2 is a plan view showing a structure of a semiconductor device 1 according to the embodiment of the present invention. The plane in the figure is defined by X and Y directions that are orthogonal to each other. An arrangement of power supply wires (including power supply lines and ground lines) in a wiring region 2 is schematically shown in FIG. 2.

The semiconductor device 1 has multiple wiring layers. In a wiring layer M1 of the multiple wiring layers, for example, a plurality of power supply lines 11 for supplying power supply potential VDD are formed along the X direction. The plurality of power supply lines 11 (11a, 11b) are formed in parallel to each other at even interval. Also, in the wiring layer M1, a plurality of ground lines 12 (12a, 12b) for supplying ground potential GND are formed along the X direction. The plurality of ground lines 12 are formed in parallel to each other at even interval. The power supply lines 11 and the ground lines 12 are formed alternately. Furthermore, in a wiring layer M4 of the multiple wiring layers, for example, a plurality of power supply lines 21 (21a) for supplying the power supply potential VDD are formed along the Y direction. The plurality of power supply lines 21 are formed in parallel to each other at even interval. Also, in the wiring layer M4, a plurality of ground lines 22 (22a) for supplying the ground potential GND are formed along the Y direction. The plurality of ground lines 22 are formed in parallel to each other at even interval. The power supply lines 21 and the ground lines 22 are formed alternately.

The plurality of power supply lines 11 formed in the wiring layer M1 and the plurality of power supply lines 21 formed in the wiring layer M4 overlap each other at a plurality of intersections. According to the present embodiment, vias 31 connecting between the power supply lines 11 and the power supply lines 21, namely, stacked vias 31 connecting between the wiring layer M1 and the wiring layer M4 are arranged at a part of the above-mentioned plurality of intersections. More specifically, as shown in FIG. 2, the vias 31 are provided for power supply lines 11a of the plurality of power supply lines 11. The vias 31 are not provided for the remaining power supply lines 11b. That is, no vias 31 are arranged at intersections 41 of the above-mentioned plurality of intersections at which the power supply lines 11b and the power supply lines 21 overlap each other.

Also, the plurality of ground lines 12 formed in the wiring layer M1 and the plurality of ground lines 22 formed in the wiring layer M4 overlap each other at a plurality of intersections. According to the present embodiment, vias 32 connecting between the ground lines 12 and the ground lines 22, namely, stacked vias 32 connecting between the wiring layer M1 and the wiring layer M4 are arranged at a part of the above-mentioned plurality of intersections. More specifically, as shown in FIG. 2, the vias 32 are provided for ground lines 12a of the plurality of ground lines 12. The vias 32 are not provided for the remaining ground lines 12b. That is, no vias 32 are arranged at intersections 42 of the above-mentioned plurality of intersections at which the ground lines 12b and the ground lines 22 overlap each other.

Furthermore, according to the present embodiment, the plurality of vias 31 (the plurality of vias 32) are arranged “regularly (systematically)” in accordance with a predetermined rule. Here, the regular arrangement means that a predetermined pattern is repeatedly arranged. In other words, the arrangement pattern of the plurality of vias 31 (the plurality of vias 32) is constituted by the repetition of the predetermined pattern.

In FIG. 2, with regard to the plurality of power supply lines 11, the plurality of vias 31 are arranged every other power supply line 11. Thus, in the wiring region 2, the power supply lines 11a and the power supply lines 11b appear alternately along the Y direction. To generalize the above, the plurality of vias 31 are arranged every n power supply lines 11 (where n is a natural number) with respect to the plurality of power supply lines 11. In this case, an interval (pitch) Py between two closest power supply lines 11a is (n+1) times the pitch between adjacent power supply lines 11. It should be noted that with respect to the plurality of power supply lines 21, the plurality of vias 31 may be also arranged every m power supply lines 21 (where m is a natural number). In this case, an interval (pitch) Px between two closest power supply lines 21a is (m+1) times the pitch between adjacent power supply lines 21. The same applies to the ground lines 12 and 22.

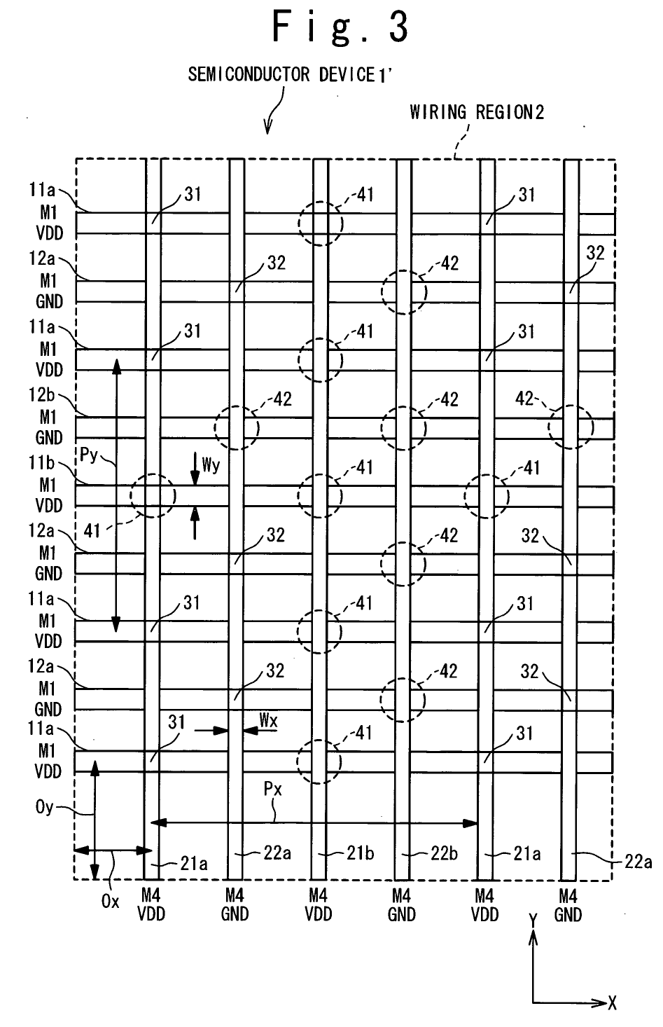

FIG. 3 shows another example of the structure of the semiconductor device 1′. In FIG. 3, the same numerals are given to the same components as those in FIG. 2, and redundant explanation will be appropriately omitted. In FIG. 3, the vias 31 are provided at intersections related to both the power supply lines 11a and the power supply lines 21a among the plurality of intersections. The vias 31 are not provided at the intersections 41 related to either the power supply lines 11b or the power supply lines 21b. Similarly, the vias 32 are provided at intersections related to both the ground lines 12a and the ground lines 22a among the plurality of intersections. The vias 32 are not provided at the intersections 42 related to either the ground lines 12b or the ground lines 22b.

In FIG. 3, the power supply lines 11 extending along the X direction appear with regularity in the Y direction in an order of “11a, 11a, 11b”. More specifically, in the Y direction, the vias 31 are provided for two successive power supply lines 11a, and are not provided for the next power supply line 11b. Also, the power supply lines 21 extending along the Y direction appear with regularity in the X direction in an order of “21a, 21b”. More specifically, with regard to the plurality of power supply lines 21, the vias 31 are arranged every other power supply line 21. Thus, the vias 31 are arranged regularly (systematically) based on a predetermined rule. The same applies to the ground lines 12 and 22, and the plurality of vias 32 are arranged regularly based on a predetermined rule.

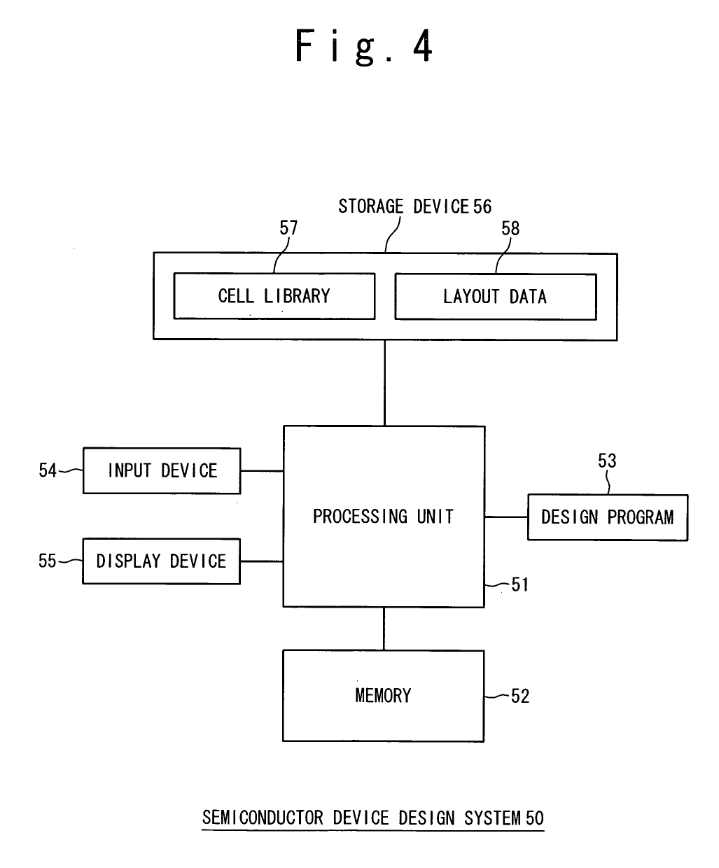

FIG. 4 is a block diagram showing a configuration of a system (CAD) for designing the semiconductor device 1 described above. The semiconductor device design system 50 includes a processing unit 51, a memory 52, a design program 53, an input device 54, a display device 55, and a storage device 56. The memory 52 is used as a work area where the layout is performed, and a layout space is constructed on the memory 52. The storage device 56 is realized, for example, by a hard disc drive. In the storage device 56, data indicative of a plurality kinds of cells are stored as a cell library 57. The plurality kinds of cells include a primitive cell such as a NAND gate and the like, and a micro cell such as a RAM and the like.

The processing unit 51 can access the memory 52 and the storage device 56. The design program (automatic layout tool) 53 is computer program executed by the processing unit 51. The design program 53 as a computer program product for designing a semiconductor device may be stored in a computer-readable medium. The input device 54 is exemplified by a keyboard and a mouse. The display device (output device) 55 is exemplified by a display. Referring to information displayed on the display, a user (designer) can input various data and commands by using the input device 54. A layout data 58 indicating the layout of the semiconductor device 1 is produced with the semiconductor device design system 50 described above. The produced layout data 58 is stored in the storage device 56, for example.

The processing unit 51 executes processing in accordance with instructions (codes) of the design program 53, and thus the following method of designing a semiconductor device is achieved.

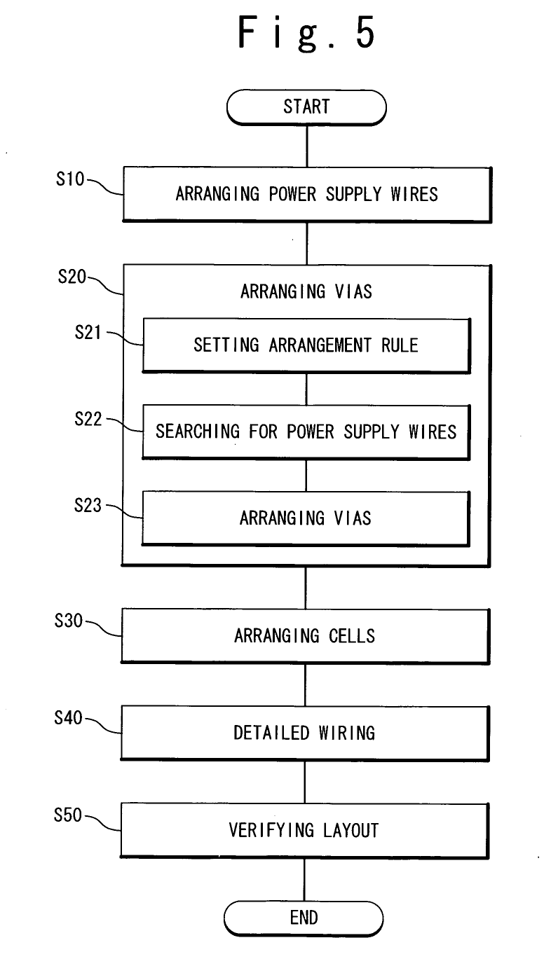

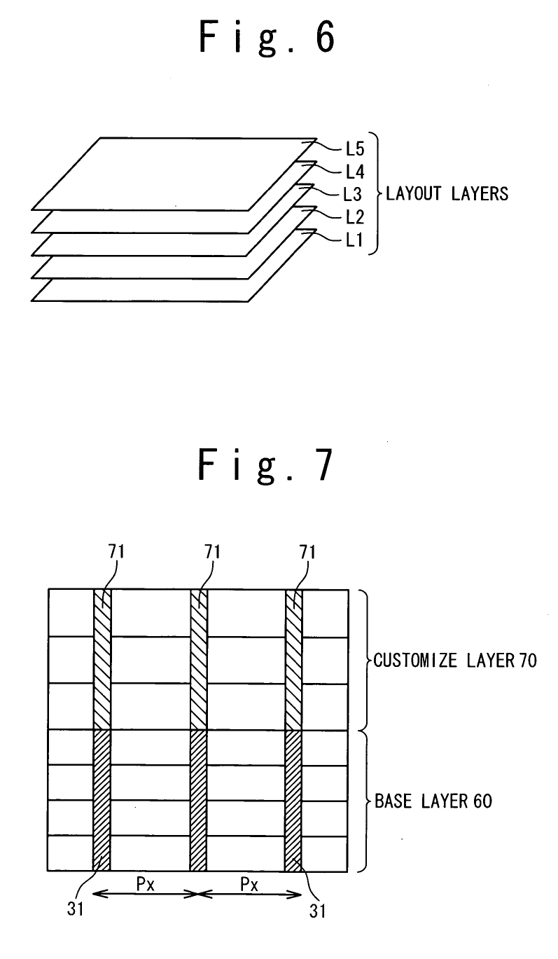

FIG. 5 is a flowchart showing an example of the method of designing a semiconductor device. First, the processing unit 51 constructs a plurality of layout layers on the memory 52. As conceptually shown in FIG. 6, the plurality of layout layers include layout layers L1 to L5, for example. The layout layer L1 corresponds to, for example, the wiring layer M1 described above. The layout layer L4 corresponds to, for example, the wiring layer M4 described above.

Next, arrangement of the power supply wires is carried out (Step S10). More specifically, in the layout layer L1, a plurality of power supply lines 11 are arranged along the X direction at regular interval (see FIG. 2). Also, in the layout layer L4, a plurality of power supply lines 21 are arranged along the Y direction at regular interval. The plurality of power supply lines 11 and the plurality of power supply lines 21 overlap each other at a plurality of intersections. The same applies to the ground lines. That is to say, in the layout layer L1, a plurality of ground lines 12 are arranged along the X direction at regular interval. Also, in the layout layer L4, the plurality of ground lines 22 are arranged along the Y direction at regular interval.

Next, arrangement of the vias 31 (the vias 32) is carried out (Step S20). More specifically, some of the above-mentioned plurality of intersections are selected as intersections where the vias 31 are to be arranged. The some intersections are selected such that the arrangement pattern thereof has regularity. To this end, an “arrangement rule” is set as a basis of the regular arrangement (Step S21). For example, by using the input device 54, the designer sets the following rules (see FIG. 2).

X direction

(1a) Net name: VDD

(1b) Offset value in the X direction: Ox

(1c) Wire pitch: Px

(1d) Wiring layer: M4

(1e) Wiring main axis: Y direction

(1f) Wire width: Wx

Y direction

(2a) Net name: VDD

(2b) Offset value in the Y direction: Oy

(2c) Wire pitch: Py

(2d) Wiring layer: M1

(2e) Wiring main axis: X direction

(2f) Wire width: Wy

In the arrangement rules, the “net name” indicates a name of a circuit or a wire in a net list. The net name “VDD” indicates a power supply line, and the net name “GND” indicates a ground line. The “offset value” indicates a distance between the origin of the wiring region 2 and a wire closest to the origin among the wires (11a, 21a) for which the designer wants to provide the vias 31. The “wire pitch” indicates a distance between wires (11a, 21a) (a distance between wire centers) for which the designer wants to provide the vias 31. The “wiring layer” indicates a target subject to “search processing” executed at the next step, i.e., Step S22. The “wiring main axis” indicates a direction in which the target wire extends. The “wire width” indicates a width of the target wire.

Next, search for structures matching the arrangement rules set at the above Step 21 is carried out. That is, search for structures for which the designer wants to provide the vias 31 is carried out (Step S22). For example, in accordance with the arrangement rule for the X direction, such power supply lines 21 are searched for that are located at coordinates “Ox+Px×i (i is an integer equal to or larger than 0)” and extends in the Y direction in the wiring layer M4. As a result, the power supply lines 21a (see FIG. 2) are automatically extracted. In addition, in accordance with the arrangement rule for the Y direction, such power supply lines 11 are searched for that are located at coordinates “Oy+Py×j (j is an integer equal to or larger than 0)” and extends in the X direction in the wiring layer M1. As a result, the power supply lines 11a (see FIG. 2) are automatically extracted.

The intersections at which the power supply lines 11a and the power supply lines 21a thus extracted overlap each other are target intersections at which the vias 31 are arranged, which are automatically selected from the all of the above-mentioned intersections. The selected partial intersections have a regular (systematic) arrangement pattern. For example, when the semiconductor device 1 shown in FIG. 2 is designed, the partial intersections are selected every other power supply line 11 with respect to the plurality of power supply lines 11. When the semiconductor device 1′ shown in FIG. 3 is designed, the number of repetitions of the power supply lines 11a may be added to the arrangement rules.

Next, the plurality of vias 31 are arranged at respective of the partial intersections selected at the Step S22 described above (Step S23). In this manner, the vias 31 are arranged automatically. The same applies to the arrangement of the vias 32 with regard to the ground lines 12 and 22.

Subsequently, data representing a desired cell is read out from the cell library 57 stored in the storage device 56, and the read cell is placed at a predetermined position in the layout space (Step S30). For example, a macro cell such as a RAM and a primitive cell such as a NAND are arranged. After that, detailed wiring is performed (Step S40). In the process, the cells are connected with each other as appropriate to obtain a desired function. Subsequently, the created layout is verified (Step S50). For example, a timing analysis of the designed LSI and the like are performed. In this manner, the layout data 58 is generated and stored in the storage device 56.

The semiconductor device 1 and the design technology concerned with the semiconductor device 1 described above provide the following effects. According to the present invention, the vias 31 or the vias 32 are arranged only at the above-mentioned partial intersections. It is therefore possible to route wires freely in the regions 41 and 42 where no vias are placed. As a result, the wiring performance is improved.

Moreover, since the vias 31 or the vias 32 are arranged only at the partial intersections, the amount of the layout data 58 can be reduced. Some chips have 10 million intersections in total. By decreasing the number of intersections at which the vias 31 and 32 are arranged, for example, down to one third of the original amount, it is possible to largely reduce the amount of the layout data 58. Thus, computing load in processing the layout data 58 (e.g. in producing mask data from the layout data 58) can be reduced.

Furthermore, according to the present invention, the plurality of vias 31 and 32 are arranged regularly (systematical) on the basis of the predetermined rule. As a result, data (language) describing the vias in the layout data 58 also have certain regularity. For example, the coordinates of the vias 31 can be simply expressed by the foregoing formula (Ox+Px×i, Oy+Py×j). Such simplicity and regularity are advantageous in terms of data amount and data compression. That is to say, according to the present invention, the amount of the layout data 58 is reduced and compression rate with respect to the layout data 58 is improved. Therefore, computing load in processing the layout data can be reduced.

Also, the above-mentioned structure of the power supply wires can be applied to an ASIC (Application Specific Integrated Circuit) and an IP (Intellectual Property) core. FIG. 7 is a sectional view conceptually showing a structure of an ASIC. According to the ASIC, a base layer 60 has a plurality of macro circuits and is manufactured in advance. In a customize layer 70 above the base layer 60, circuits are formed in accordance with the user's request. When the structure of the power supply wires according to the present invention is applied to the ASIC, the power supply wires are formed in the base layer 60 beforehand. In this case, the vias 71 in the customize layer 70 are formed based on the same rule as applied to the base layer 60. That is, as shown in FIG. 7, the vias 71 in the customize layer 70 are formed at positions corresponding to the vias 31 in the base layer 60. According to the present invention, the arrangement of the vias 31 in the base layer 60 has some regularity. Thus, when arranging the vias 71 in the customize layer 70, the user can easily arrange the vias 71 on the basis of the regularity. In other words, the user can easily recognize where to arrange the vias 71. Moreover, the above-mentioned power supply structure can be used also in designing an IP core such as a CPU. As described above, the designing of the ASIC and the IP core becomes easier according to the present invention.

It is apparent that the present invention is not limited to the above embodiment, and that may be modified and changed without departing from the scope and spirit of the invention.

What is claimed is:

1. A semiconductor device comprising:
a plurality of first power supply wires formed in a first wiring layer;
a plurality of second power supply wires formed in a second wiring layer and overlapping said plurality of first power supply wires at a plurality of intersections; and
a plurality of vias arranged regularly at a part of said plurality of intersections and connecting between said first wiring layer and said second wiring layer.

2. The semiconductor device according to claim 1,
wherein an arrangement pattern of said plurality of vias includes repetition of a predetermined pattern.

3. The semiconductor device according to claim 1,
wherein said plurality of first power supply wires are formed along a first direction, and said plurality of vias are arranged every n (n is a natural number) first power supply wires with respect to said plurality of first power supply wires.

4. The semiconductor device according to claim 3,
wherein said plurality of second power supply wires are formed along a second direction which intersects with said first direction, and said plurality of vias are arranged every m (m is a natural number) second power supply wires with respect to said plurality of second power supply wires.

5. The semiconductor device according to claim 1,
wherein said plurality of first power supply wires are formed at even intervals, and said plurality of second power supply wires are formed at even interval.

6. The semiconductor device according to claim 2,
wherein said plurality of first power supply wires are formed at even intervals, and said plurality of second power supply wires are formed at even interval.

7. The semiconductor device according to claim 3,
wherein said plurality of first power supply wires are formed at even intervals, and said plurality of second power supply wires are formed at even interval.

8. The semiconductor device according to claim 4,
wherein said plurality of first power supply wires are formed at even intervals, and said plurality of second power supply wires are formed at even interval.

9. A computer program product for designing a semiconductor device, embodied on a computer-readable medium and comprising code that, when executed, causes a computer having a memory to perform the following:
(A) constructing a first layout layer and a second layout layer on said memory;
(B) arranging a plurality of first power supply wires in said first layout layer;
(C) arranging a plurality of second power supply wires in said second layout layer, said plurality of second power supply wires overlapping said plurality of first power supply wires at a plurality of intersections;
(D) selecting a part of said plurality of intersections; and
(E) arranging a plurality of vias at respective of said selected part of intersections.

10. The computer program product according to claim 9,
wherein in said (D) step, said partial intersections are selected from said plurality of intersections such that said partial intersections have repetition of a predetermined pattern.

11. The computer program product according to claim 10,
wherein said (B) step includes arranging said plurality of first power supply wires along a first direction, and
said (D) step includes selecting said partial intersections every n (n is a natural number) first power supply wires with respect to said plurality of first power supply wires.

12. The computer program product according to claim 11,
wherein said (C) step includes arranging said plurality of second power supply wires along a second direction which intersects with said first direction, and
said (D) step includes selecting said partial intersections every m (m is a natural number) second power supply wires with respect to said plurality of second power supply wires.
